(19) United States
(12) Patent Application Publication
(10) Pub. No.: US 2022/0352340 A1
(43) Pub. Date: Nov. 3, 2022

(54) GATE STRUCTURE AND MANUFACTURING METHOD THEREOF

(71) Applicant: CHANGXIN MEMORY TECHNOLOGIES, INC., Hefei City (CN)

(72) Inventors: Shuhao ZHANG, Hefei City (CN); Ning Li, Hefei City (CN)

(21) Appl. No.: 17/648,202

(22) Filed: Jan. 18, 2022

Related U.S. Application Data
(63) Continuation of application No. PCT/CN2021/111883, filed on Aug. 10, 2021.

(30) Foreign Application Priority Data
Apr. 30, 2021 (CN) 202110483826.8

(51) Int. Cl. H01L 29/49; H01L 21/28

(52) U.S. Cl. CPC H01L 29/4966; H01L 21/28088

(57) ABSTRACT

This disclosure provides a gate structure and a manufacturing method thereof. A gate structure, including: a gate dielectric layer, attached to a semiconductor substrate; a gate material layer, attached to the gate dielectric layer, wherein the gate material layer is made of atomic crystals WSe2 or MoSe2; and a gate metal layer, attached to the gate material layer, wherein a gate electrode is led out from the gate metal layer.

### CROSS-REFERENCE TO RELATED APPLICATIONS

This disclosure is a continuation application of International Patent Application No. PCT/CN2021/111883, titled “GATE STRUCTURE AND MANUFACTURING METHOD THEREOF” and filed on Aug. 10, 2021, which claims the priority to Chinese Patent Application No. 202110483826.8, titled “GATE STRUCTURE AND MANUFACTURING METHOD THEREOF” and filed with the China National Intellectual Property Administration (CNIPA) on Apr. 30, 2021. The entire contents of International Patent Application No. PCT/CN2021/111883 and Chinese Patent Application No. 202110483826.8 are incorporated herein by reference.

### TECHNICAL FIELD

This disclosure relates to, but is not limited to, a gate structure and a manufacturing method thereof.

### BACKGROUND

Metal-oxide-semiconductor field-effect transistors (MOSFET) are a type of transistors widely applied to analog circuits and digital circuits. In a MOSFET transistor, a doped semiconductor material is used as a semiconductor substrate, two inverse diffusion layers are formed by ion doping on the semiconductor substrate and are respectively connected to a source and a drain, and a voltage is applied to a gate structure to control a charge channel formed between a source region and a drain region.

The gate structure of the MOSFET transistor includes an oxide layer, a polycrystalline silicon material (poly) layer, an adhesive layer, and a metal layer. The metal layer is used to lead out a gate electrode. The adhesive layer is used to connect the poly layer to the metal layer. The ploy layer is used to adjust a work function of the gate structure by using implanted N-type or P-type ions, and has a same conductivity type as the MOSFET transistor, to reduce a metal semiconductor barrier and form ohmic contact. As a dielectric layer, the oxide layer is used to prevent electric leakage at a gate caused when charges at the gate are diffused to a channel region.

A work function of a metal structure of an NMOS or PMOS transistor needs to be changed by adjusting a type of ions implanted into the poly layer in the gate structure, to reduce a barrier between the metal gate and a semiconductor channel and form ohmic contact. Consequently, the gate structure of the MOSFET transistor and the production process in a manufacturing process are relatively complex.

### SUMMARY

This disclosure provides a gate structure and a manufacturing method thereof, to overcome a prior-art problem that a gate structure of a transistor and a manufacturing process thereof are relatively complex.

This disclosure provides a gate structure, including: a gate dielectric layer, attached to a semiconductor substrate; a gate material layer, attached to the gate dielectric layer, where the gate material layer is made of an atomic crystal WSe₂ or MoSe₂; and a gate metal layer, attached to the gate material layer, where a gate electrode is led out from the gate metal layer.

This disclosure provides a method for manufacturing a gate structure, applied to manufacture the gate structure provided in this disclosure. The manufacturing method including: obtaining a semiconductor substrate; forming a gate dielectric layer on a surface of the substrate; depositing a gate material layer on a surface of the gate dielectric layer, where the gate material layer is made of an atomic crystal WSe₂ or MoSe₂; conducting coating and development processing on the gate material layer and the gate dielectric layer to obtain the gate dielectric layer and the gate material layer at a preset position; and depositing a gate metal layer on a surface of the gate material layer.

### BRIEF DESCRIPTION OF THE DRAWINGS

To describe the technical solutions in the embodiments of this disclosure or in the prior art more clearly, the following briefly describes the accompanying drawings required for the embodiments or the prior art. Apparently, the accompanying drawings in the following description show merely some embodiments of this disclosure, and persons of ordinary skill in the art may still derive other accompanying drawings from these accompanying drawings without creative efforts.

FIG. 1 is schematic structural diagram of a MOSFET transistor;

FIG. 2 is schematic diagram of a gate structure;

FIG. 3 is a schematic structural diagram of an embodiment of a gate structure according to this disclosure;

FIG. 4 is a schematic diagram of photoluminescence spectra of atomic crystal WSe₂;

FIG. 5 is an energy band diagram of atomic crystals WSe₂;

FIG. 6 is a schematic diagram of a metal gate structure corresponding to a P-type work function according to this disclosure;

FIG. 7 is a schematic diagram of a metal gate structure corresponding to an N-type work function according to this disclosure;

FIG. 8 is a schematic diagram of conductive characteristics of a MOSFET transistor using a gate structure made of atomic crystals according to this disclosure;

FIG. 9 is a schematic flowchart of an embodiment of a manufacturing method of a gate structure according to this disclosure;

FIG. 10 is a schematic structural diagram of processes in an embodiment of a manufacturing method of a gate structure according to this disclosure; and

FIG. 11 is a schematic structural diagram of processes in another embodiment of a manufacturing method of a gate structure according to this disclosure.

### DETAILED DESCRIPTION

The following clearly and completely describes the technical solutions in the embodiments of this disclosure with reference to accompanying drawings in the embodiments of this disclosure. Apparently, the described embodiments are merely a part rather than all of the embodiments of this disclosure. All other embodiments obtained by persons of ordinary skill in the art based on the embodiments of this disclosure without creative efforts shall fall within the protection scope of this disclosure.

In the specification, claims, and accompanying drawings of this disclosure, the terms “first”, “second”, “third”, “fourth”, and the like (if existent) are intended to distinguish between similar objects but do not necessarily indicate a specific order or sequence. It should be understood that the data termed in such a way are interchangeable in proper circumstances such that the embodiments of the present disclosure described herein can be implemented in orders except the order illustrated or described herein. Moreover, the terms “include”, “contain” and any other variants mean to cover the non-exclusive inclusion, for example, a process, method, system, product, or device that includes a list of steps or units is not necessarily limited to those steps or units, but may include other steps or units not expressly listed or inherent to such a process, method, product, or device.

Before the embodiments of this disclosure are formally described, scenarios to which this disclosure is applied and problems existing in the prior art are first described with reference to the accompanying drawings. This disclosure is applied to a MOSFET transistor. The MOSFET transistor can be cut off or switched on through voltage control. Therefore, as switch components, MOSFET transistors are widely applied in analog circuits and digital circuits.

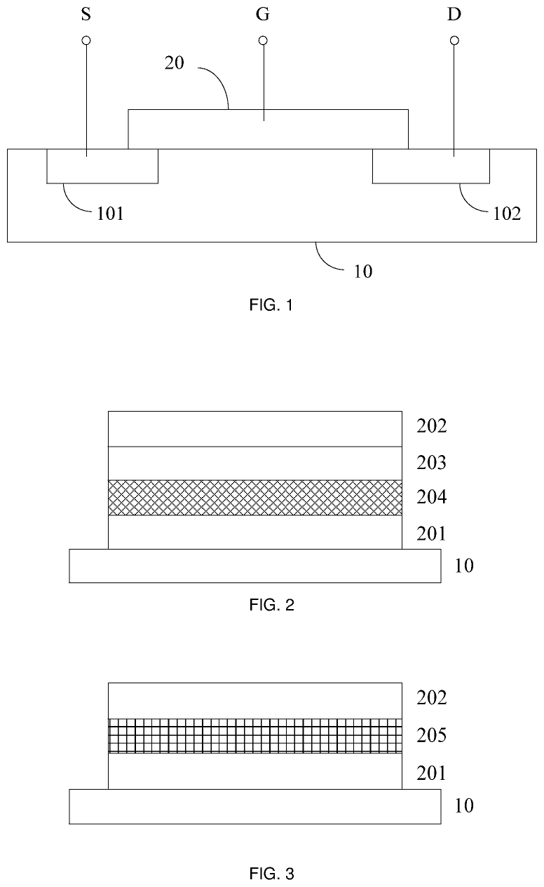

In some embodiments, FIG. 1 is a schematic structural diagram of a MOSFET transistor. The MOSFET transistor shown in FIG. 1 is disposed on a semiconductor substrate 10. A first diffusion region 101 and a second diffusion region 102 are disposed on the semiconductor substrate 10. An electrode S may be led out from the first diffusion region 101 to be used as a source of the MOSFET transistor, and an electrode D may be led out from the second diffusion region 102 to be used as a drain of the MOSFET transistor. In addition, a gate structure 20 may further be disposed on the substrate 10 of the MOSFET transistor, and the gate structure 20 may be used to lead out an electrode G as a gate of the MOSFET transistor, such that a switched-on state or a cut-off state of a channel formed between the first diffusion region 101, the second diffusion region 102, and the substrate can be controlled by a voltage on the electrode G through a dielectric layer.

In some embodiments, when the MOSFET transistor is an N-type conductive transistor, the first diffusion region 101 and the second diffusion region 102 are N-type diffusion regions, and the substrate 10 forms a P-type active region. Under the control of the gate G, conduction and cut-off of a current between the electrode S and the electrode D are implemented through conduction and cut-off of an N-type channel between the first diffusion region 101 and the second diffusion region 102. In some other embodiments, when the MOSFET transistor is a P-type conductive transistor, the first diffusion region 101 and the second diffusion region 102 are P-type diffusion regions, and the substrate 10 forms an N-type active region. Under the control of the gate G, conduction and cut-off of a current between the electrode S and the electrode D are implemented through switch-on and cut-off of a P-type channel between the first diffusion region 101 and the second diffusion region 102.

More specifically, in some embodiments, FIG. 2 is a schematic diagram of a gate structure. FIG. 2 shows a gate structure part of the MOSFET transistor shown in FIG. 1. The gate structure part formed on the substrate 10 includes an oxide layer 201, a polycrystalline silicon material (poly) layer 204, an adhesive layer 203, and a metal layer 202 from bottom to top. The oxide layer 201 may be made of a material such as silicon oxide, is used as a dielectric layer, and can be used to prevent electric leakage at a gate caused when charges at the gate are diffused to a channel region in the substrate 10. The metal layer 202 may be made of a conductive metal material, and is used to lead out the gate electrode G. The adhesive layer 203 may be made of TiN or other materials, and is used to connect the poly layer 204 and the metal layer 202. The ploy layer 204 may be formed by growing amorphous silicon by using a chemical vapor deposition (CVD) method and then conducting annealing crystallization. A work function of the poly layer is adjusted based on a type of ions implanted into the poly layer, to adjust a type of a work function of the metal gate to a P-type or an N-type, such that the metal gate 20 can be in good ohmic contact with an N-type or P-type conductive channel formed in the substrate 10. This is easy for implementation of switch-on and cut-off of the channel.

However, in the embodiment shown in FIG. 2, the work function of the metal gate of the MOSFET transistor needs to be changed by adjusting the type of the ions implanted into the poly layer 204 in the gate structure, to reduce a barrier between the metal gate and the semiconductor channel and form ohmic contact. Consequently, the gate structure of the MOSFET transistor and the production process in a manufacturing process are relatively complex. In addition, the ions implanted in the ion implantation process affects the reliability of the MOSFET transistor device. Moreover, the adhesive layer 203 needs to be additionally disposed on the poly layer 204 of the MOS transistor to connect the poly layer 204 to the metal layer 202. This further increases the complexity and costs of the gate structure of the MOSFET transistor.

Therefore, this disclosure provides a gate structure and a manufacturing method thereof. Atomic crystals whose work function depends on a thickness serve as a gate material in a gate structure, such that a work function of the gate structure can be adjusted by forming atomic crystal layers of different thicknesses, thereby reducing the complexity of the gate structure of the MOSFET transistor and simplifying a production process in a manufacturing process. Moreover, the work function is not adjusted in an ion implantation manner, such that impact on the reliability of the MOSFET transistor device caused due to implanted ions is avoided. In addition, when the atomic crystals are a tungsten compound or other atomic materials, the atomic crystals and a gate metal layer made of metal tungsten W or other materials have good natural viscosity, a gate material can be directly connected to gate metal without additionally providing an adhesive layer in the gate structure. This further reduces the complexity of the gate structure of the MOSFET transistor. Moreover, because the atomic crystal layers are directly bonded by van der Waals force instead of chemical bonds, the atomic crystals have more clutter-free surfaces, thereby reducing interface charges and traps.

The following describes in details the technical solutions of this disclosure with reference to specific embodiments. The following several specific embodiments may be combined with each other, and same or similar concepts or processes may not be repeated in some embodiments.

FIG. 3 is a schematic structural diagram of an embodiment of a gate structure according to this disclosure. The gate structure shown in FIG. 3 may be applied to the MOSFET transistor shown in FIG. 1, and a structure other than the gate structure is not limited in FIG. 3. Specifically, the gate structure in the embodiment shown in FIG. 3 is disposed on a surface of a semiconductor substrate 10. An example in which the semiconductor substrate 10 is disposed below the gate structure is used in FIG. 3. In the figure, the gate structure includes a gate dielectric layer 201, a gate material layer 205, and a gate metal layer 202 from bottom to top.

The semiconductor substrate 10 may be a Si substrate, a Ge substrate, a SiGe substrate, an SOI substrate, or a GOI substrate, may be a substrate including another semiconductor or a compound semiconductor, such as a GaAs, InP, or SiC substrate, may be a laminated structure such as Si/SiGe, or may be another epitaxial structure such as SGOI.

The gate dielectric layer 201 is attached to the semiconductor substrate 10, and may be made of one or any mixture of two or more from the group consisting of SiOₓ, AlOₓ, SiC, HfOₓ, TiOₓ, h-BN, and SiNₓ, may be a mixture of two or more from the group consisting of the foregoing substances, or may be made of an oxide, a mixture, or the like in another form.

A bottom part of the gate material layer 205 is attached to the gate dielectric layer 201, and a top part of the gate material layer 205 is attached to the gate metal layer 202. In this embodiment of this disclosure, the gate material layer 205 is made of atomic crystals WSe₂ or atomic crystals MoSe₂.

The gate metal layer 202 is attached to the gate material layer 205, and may be made of a metallic conductor such as one or a mixture of two or more from the group consisting of W, Mo, Al, Au, Cu, Ni, Ti, Cr, Ag, Pt, and Pd.

With reference to the accompanying drawings, the following describes, by using the atomic crystals WSe₂ as an example, characteristics of the atomic crystals in the gate material layer 205 provided in this disclosure.

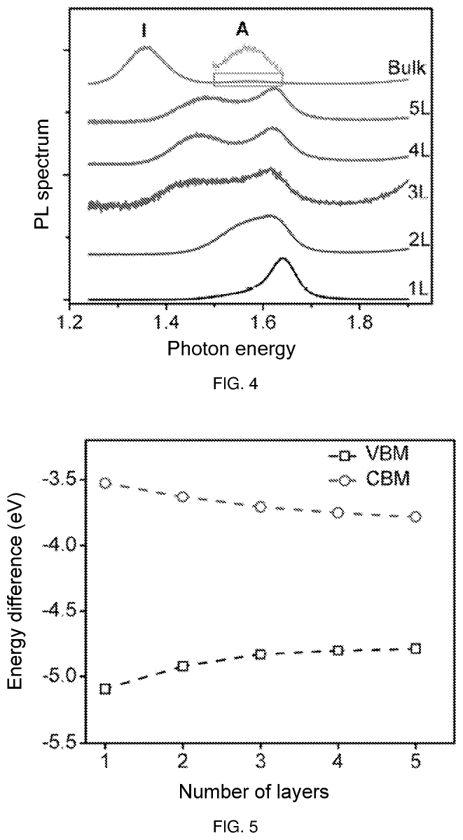

FIG. 4 is a schematic diagram of photoluminescence spectra (PL spectra) of atomic crystals WSe₂. The photoluminescence means: Under the excitation of light, electrons in the atomic crystals transit from valence bands to conduction bands and leave holes in the valence bands, the electrons and holes in their respective conduction and valence bands each enter a lowest unoccupied excited state by relaxation and keep in a quasi-equilibrium state, and the electrons and holes in the quasi-equilibrium state form a spectrum chart of intensity or energy distribution of light of different wavelengths through recombination luminescence. FIG. 4 shows PL spectra (Normalized PL) that are presented under the excitation of different photon energy (unit: eV) and that are of atomic crystal WSe₂ of different layer thicknesses obtained through layer stacking. It can be learned that a band gap of a PL spectrum vary with a thickness of the atomic crystals and intensity of the PL spectrum is strongly correlated with a number of layers.

FIG. 5 is an energy band diagram of atomic crystals WSe₂. It can be learned from FIG. 5 that, an energy difference (unit: eV) of work functions of the atomic crystals WSe₂ can be adjusted by adjusting a horizontal ordinate, namely a thickness (a number of layers, L) of the atomic crystals WSe₂. This proves that the atomic crystals WSe₂ are a material whose work function depends on a thickness.

In some embodiments, based on the characteristic of the atomic crystals whose work function depends on a thickness, a work function of the gate structure provided in the embodiment shown in FIG. 3 in this disclosure is also related to a thickness of the gate material layer made of these atomic crystals. Therefore, gate material layers of different thicknesses are formed, and the gate structures are classified into a metal gate corresponding to a P-type work function and a metal gate corresponding to an N-type work function.

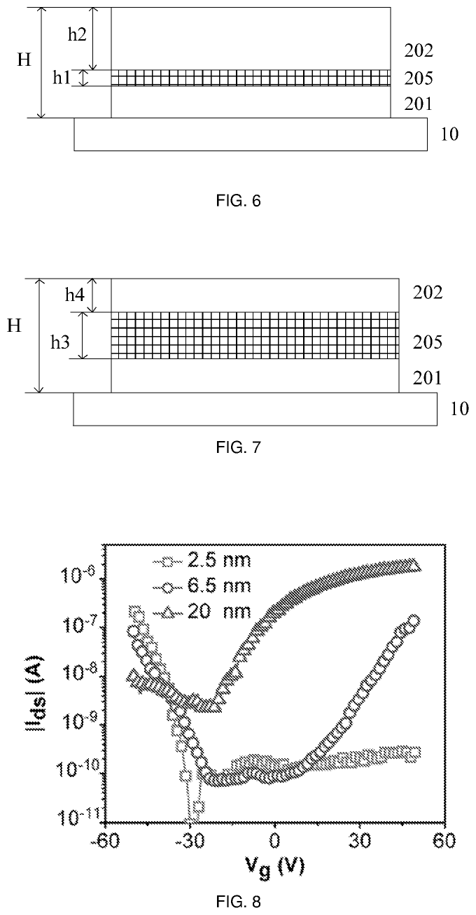

For example, FIG. 6 is a schematic diagram of a metal gate structure corresponding to a P-type work function according to this disclosure. FIG. 7 is a schematic diagram of a metal gate structure corresponding to an N-type work function according to this disclosure. A thickness h1 of a metal gate material layer 205 that corresponds to the P-type work function and that is shown in FIG. 6 is smaller than a thickness h3 of a metal gate material layer 205 that corresponds to the N-type work function and that is shown in FIG. 7.

In some embodiments, a preset thickness of the gate material layers 205 may be set, a gate material layer whose thickness is less than the preset thickness may have a P-type work function, and a gate material layer whose thickness is greater than the preset thickness may have an N-type work function. For example, FIG. 8 is a schematic diagram of conductive characteristics of a MOSFET transistor using a gate structure made of atomic crystals according to this disclosure. The preset thickness is recorded as 6.5 nm. It can be learned that when the thickness of the gate material layer 205 is 2.5 nm, and when a voltage lower than 0 V is applied to the gate G of the MOSFET transistor, as an absolute value of the voltage increases, a current Ids in the MOSFET transistor from an electrode D to an electrode S increases; and when a voltage higher than 0 V is applied to the gate G, a voltage change has little impact on the current Ids, such that the entire MOSFET transistor belongs to a P-type conductivity type. When the thickness of the gate material layer 205 is 20 nm, and when a voltage higher than 0 V is applied to the gate of the MOSFET transistor, as the voltage increases, the current Ids in the MOSFET transistor from the electrode D to the electrode S increases; and when a voltage lower than 0 V is applied to the gate G, a voltage change has little impact on the current Ids, such that the entire MOSFET transistor belongs to an N-type conductivity type.

In some embodiments, in the gate structure provided in this embodiment of this disclosure, a thickness of the gate material layer corresponds to a conductivity type of the gate structure, such that the thicknesses of the gate material layer varies with the conductivity type of the gate structure, and a height of the MOSFET transistor using the gate structure varies. Therefore, in the gate structure provided in this embodiment of this disclosure, the thickness of the gate metal layer may be correspondingly set to make overall heights of the gate structure of the MOSFET transistor remain the same when conductivity types of the gate structure are not the same.

For example, with reference to FIG. 6 and FIG. 7, when the thickness of the metal gate material layer 205 that corresponds to the P-type work function and that is shown in FIG. 6 is h1, a thickness of the gate metal layer 202 is h2, and an overall height of a part that is of the gate structure and that is on the substrate 10 is H. When the thickness of the metal gate material layer 205 that corresponds to the N-type work function and that is shown in FIG. 7 is h3, a thickness of the gate metal layer 202 is h4, and an overall height of a part that is of the gate structure and that is on the substrate 10 is also H.

To sum up, according to the gate structure provided in this embodiment of this disclosure, the gate material layer in the gate structure is made of the atomic crystals WSe₂ or the atomic crystals MoSe₂ whose work function depends on a thickness. Therefore, a work function of the gate structure of the MOSFET transistor can be adjusted by forming atomic crystal layers of different thicknesses, thereby reducing the complexity of the gate structure of the MOSFET transistor and simplifying a production process in a manufacturing process. In addition, because the atomic crystal layers are directly bonded by van der Waals force instead of chemical bonds, the atomic crystals have more clutter-free surfaces. Moreover, the work function of the gate structure made of the atomic crystals is not adjusted in an ion implantation manner shown in FIG. 2, such that impact on the reliability of the MOSFET transistor device caused due to implanted ions is avoided. Furthermore, because a tungsten compound such as atomic crystals WSe₂ and the gate metal layer made of metal tungsten W or other materials have good natural viscosity, the gate material layer can be directly connected to the gate metal layer without additionally providing the adhesive layer such as a TiN layer shown in FIG. 2 in the gate structure. This further reduces the complexity and manufacturing costs of the gate structure of the MOSFET transistor.

In addition, by using the CVD method, the atomic crystals WSe₂ in the gate structure in this embodiment of this disclosure can be directly grown on a surface of the gate dielectric layer made of silicon oxide, sapphire, or the like. This further simplifies a manufacturing process of the gate structure compared with a case in which annealing crystallization further needs to be conducted during growth of the ploy layer of the gate structure shown in FIG. 2 after the CVD method is conducted. A manufacturing method of a gate structure provided in the embodiments of this disclosure is described below with reference to the accompanying drawings.

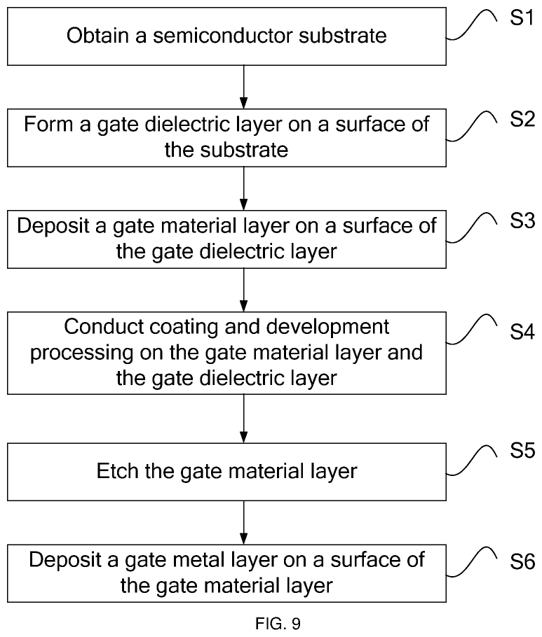

FIG. 9 is a schematic flowchart of an embodiment of a manufacturing method of a gate structure according to this disclosure. The method shown in FIG. 9 includes the following steps:

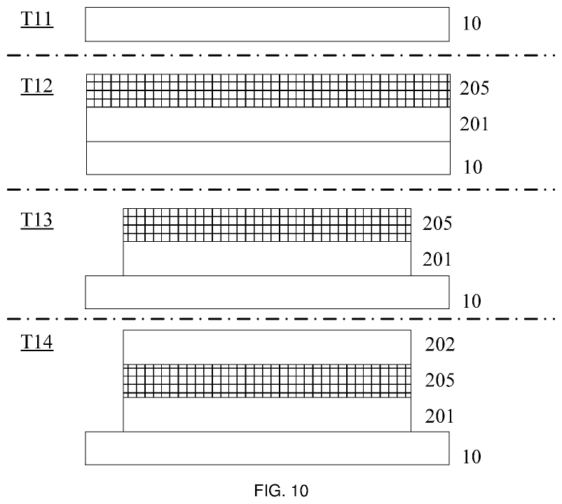

S1: Obtain a semiconductor substrate. FIG. 10 is a schematic structural diagram of processes in an embodiment of a manufacturing method of a gate structure according to this disclosure. S1 corresponds to process T11 in FIG. 10: Obtain a semiconductor substrate 10.

S2: Form a gate dielectric layer on a surface of the substrate. S2 corresponds to process T12 in FIG. 10: Form a gate dielectric layer 201 in an entire surface area of the semiconductor substrate 10.

S3: Deposit a gate material layer on a surface of the gate dielectric layer. S3 corresponds to process T12 in FIG. 10: Form a gate material layer 205 in an entire surface area of the gate dielectric layer 201. In addition, a thickness of the grown gate material layer is related to a work function type of a gate structure. For example, when the gate structure corresponds to a P-type work function, the thickness of the deposited gate material layer may be 2.5 nm; and when the gate structure corresponds to an N-type work function, the thickness of the deposited gate material layer may be 20 nm. In some embodiments, when the gate material layer 205 is atomic crystals WSe₂, in S3, a method such as CVD or ALD may be specifically used to grow WSe₂ on the gate dielectric layer 201.

S4: Conduct coating and development processing on the gate material layer 205 and the gate dielectric layer 201. S4 corresponds to process T13 in FIG. 10: Obtain a gate dielectric layer 201 and a gate material layer 205 at a preset position on the substrate 10. The gate dielectric layer and the gate material layer that are not at the preset position and that are grown on the substrate 10 in T12 will be etched. The preset position may be a position of a gate of a MOSFET transistor, and is marked by using a mask window or in another manner, such that during coating and development, the preset position may be shielded by the mask window, and an area except the preset position is exposed. The gate dielectric layer and the gate material layer that are not at the preset position are etched, and a preset area is protected from being etched by using the mask window.

S6: Deposit a gate metal layer 202 on a surface of the gate material layer 205. S6 corresponds to process T14 in FIG. 10: Form a gate metal layer 202 in an entire surface area of the gate material layer 205.

S1-S4 and S6 shown in FIG. 9 and the processes shown in FIG. 10 can be applied to a manufacturing method of a gate structure corresponding to a case in which one gate structure is separately fabricated on the substrate 10. When multiple gate structures need to be fabricated on the substrate 10 and the multiple gate structures correspond to different conductivity types, after S4 and before S6, S5 further needs to be conducted based on conductivity types of different gate structures to etch the gate material layer that has been grown, to adjust thicknesses of the different gate material layers.

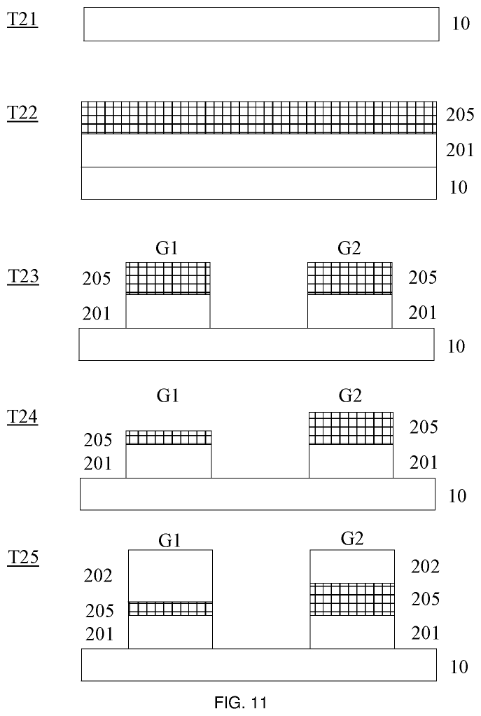

FIG. 11 is a schematic structural diagram of processes in another embodiment of a manufacturing method of a gate structure according to this disclosure. For example, two gate structures G1 and G2 are both disposed on a substrate 10. The gate structure G1 corresponds to a P-type work function, and the gate structure G2 corresponds to an N-type work function. In this case, states T21 and T22 shown in FIG. 11 are the same as T11 and T12, and details are not described herein again. Subsequently, in a state T23, gate material layers 205 and gate dielectric layers 201 at preset positions at which the two gate structures G1 and G2 are located can be retained through coating and development processing. Because a thickness of a gate material layer corresponding to a P-type work function is smaller than a thickness of a gate material layer corresponding to an N-type work function, in a state T24, the gate material layer of the gate structure G1 is etched to make a thickness of the gate material layer of the gate structure G1 correspond to the P-type work function. In this case, a thickness of the gate material layer generated in T22 may correspond to the N-type work function, such that G2 does not need to be etched in T24. This reduces an etching area and improves the manufacturing efficiency.

Persons of ordinary skill in the art may understand that all or some of the steps of the method embodiments may be implemented by a program instructing relevant hardware. The program may be stored in a computer-readable storage medium. When the program runs, the steps of the method embodiments are performed. The foregoing storage medium includes any medium that can store program code, such as a ROM, a RAM, a magnetic disk, or an optical disc.

Finally, it should be noted that the above embodiments are merely used to explain the technical solutions of this disclosure, but are not intended to limit this disclosure. Although this disclosure is described in detail with reference to the foregoing embodiments, persons of ordinary skill in the art should understand that they can still modify the technical solutions described in the foregoing embodiments, or make equivalent substitutions on some or all technical features therein. These modifications or substitutions do not make the essence of the corresponding technical solutions deviate from the spirit and scope of the technical solutions of the embodiments of this disclosure.

1. A gate structure, comprising:
a gate dielectric layer, attached to a semiconductor substrate;
a gate material layer, attached to the gate dielectric layer, wherein the gate material layer is made of atomic crystals WSe₂ or MoSe₂; and
a gate metal layer, attached to the gate material layer, wherein a gate electrode is led out from the gate metal layer.

2. The gate structure according to claim 1, wherein
a work function of the gate structure is related to a thickness of the gate material layer.

3. The gate structure according to claim 2, wherein
when the gate structure is of a P-type conductivity type, the thickness of the gate material layer is less than a preset thickness value; and
when the gate structure is of an N-type conductivity type, the thickness of the gate material layer is greater than the preset thickness value.

4. The gate structure according to claim 3, wherein
the preset thickness value is 6.5 nm.

5. The gate structure according to claim 1, wherein
the gate metal layer is made of one or a mixture of two or more from a group consisting of W, Mo, Al, Au, Cu, Ni, Ti, Cr, Ag, Pt, and Pd.

6. The gate structure according to claim 5, wherein
a sum of a thicknesses of the gate metal layer and the gate material layer when the gate structure is of a P-type conductivity type is equal to a sum of a thicknesses of the gate metal layer and the gate material layer when the gate structure is of an N-type conductivity type.

7. The gate structure according to claim 1, wherein
the gate dielectric layer is made of one or a mixture of two or more from a group consisting of SiOₓ, AlOₓ, SiC, HfOₓ, TiOₓ, h-BN, and SiNₓ.

8. A method for manufacturing a gate structure, comprising:
obtaining a semiconductor substrate;
forming a gate dielectric layer on a surface of the semiconductor substrate;
depositing a gate material layer on a surface of the gate dielectric layer, wherein the gate material layer is made of atomic crystals WSe₂ or MoSe₂;
conducting coating and development processing on the gate material layer and the gate dielectric layer to obtain the gate dielectric layer and the gate material layer at a preset position; and
depositing a gate metal layer on a surface of the gate material layer.

9. The method according to claim 8, wherein before the depositing a gate metal layer on a surface of the gate material layer, the method further comprises:
etching the gate material layer based on a conductivity type of the gate structure, to adjust thicknesses of different gate material layers.

10. The method according to claim 9, wherein
a work function of the gate structure is related to a thickness of the gate material layer.

11. The method according to claim 10, wherein
when the gate structure is of a P-type conductivity type, the thickness of the gate material layer is less than a preset thickness value; and
when the gate structure is of an N-type conductivity type, the thickness of the gate material layer is greater than the preset thickness value.

12. The method according to claim 11, wherein
the preset thickness value is 6.5 nm.

13. The method according to claim 8, wherein
the gate metal layer is made of one or a mixture of two or more from a group consisting of W, Mo, Al, Au, Cu, Ni, Ti, Cr, Ag, Pt, and Pd.

14. The method according to claim 13, wherein
a sum of a thicknesses of the gate metal layer and the gate material layer when the gate structure is of a P-type conductivity type is equal to a sum of a thicknesses of the gate metal layer and the gate material layer when the gate structure is of an N-type conductivity type.

15. The method according to claim 8, wherein
the gate dielectric layer is made of one or a mixture of two or more from a group consisting of SiOₓ, AlOₓ, SiC, HfOₓ, TiOₓ, h-BN, and SiNₓ.
